(19) United States
(12) Patent Application Publication
(10) Pub. No.: US 2006/0164115 A1
(43) Pub. Date: Jul. 27, 2006

(54) Defect analyzing device for semiconductor integrated circuits, system therefor, and detection method

(76) Inventors: Yasumaro Komiya, Yokohama (JP); Shuji Kikuchi, Yokohama (JP); Koichi Uesaka, Yokohama (JP); Tadanobu Toba, Yokohama (JP); Keiichi Yamamoto, Yokohama (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 10/533,127

(22) PCT Filed: Oct. 29, 2003
(86) PCT No.: PCT/JP03/13869

§ 371 Date: Oct. 7, 2005

(30) Foreign Application Priority Data
Oct. 29, 2002 (JP) 2002-313618

(51) Int. Cl. G01R 31/26

(52) U.S. Cl. 324/765

(57) ABSTRACT

The present invention aims at performing a semiconductor integrated circuit defect analysis with a simplified analysis apparatus and simplifying a defect analysis work. A defect analysis apparatus for a semiconductor integrated circuit is characterized in that a presence/absence of a defect is detected by irradiating an electromagnetic field from a probe to the semiconductor integrated circuit and detecting an electric characteristic variation such as a power supply current variation in the semiconductor integrated circuit.

### TECHNICAL FIELD

The present invention relates to a semiconductor defect analysis apparatus and system and a semiconductor defect analysis method for supporting semiconductor defect analysis, and also relates to a semiconductor manufacture method.

### BACKGROUND ART

Shortening a defect analysis time in the manufacture processes for semiconductor integrated circuits (hereinafter called LSI) is a very important issue from the standpoint of shortening a process configuration period and starting up quickly a process line. A delay in defect analysis leads to a delay in process configuration.

However, recent LSIs with advanced miniaturization and high integration have an immense number of wiring patterns, resulting in a long analysis time. There occur the cases that a defect position cannot be identified and the analysis of LSI defects such as disconnection defect becomes difficult.

As a conventional example of defect analysis techniques for detecting LSI wiring breakdown failures, there are JP-A-10-10208 and JP-A-2001-141776.

According to Japanese Patent Laid-open Publication No. JP-A-10-10208, an electron beam is irradiated to an arbitrary disconnection defect portion with an EB tester to change a potential at the defective portion between an intermediate potential and a low potential or between an intermediate potential and a high potential and obtain a potential image changing the potential only at the disconnection defect portion or at circuit connected to the disconnection defect portion to thereby identify the defective portion (refer to JP-A-10-10208).

According to JP-A-2001-141776, instead of electron beam irradiation, a magnetic field generating head is used in which a magnetic field is locally applied to a specimen to generate a potential change due to a generated electromotive force and obtain a potential image of the potential change to thereby detect whether there is any defect (refer to JP-A-2001-141776).

### DISCLOSURE OF THE INVENTION

The EB tester used in JP-A-10-10208 uses an electron beam in order to generate a potential change at a disconnection defect and obtain a potential image. It is therefore necessary to use a system capable of maintaining a vacuum state, resulting in a huge structure of the whole system. More specifically, an EB tester is a collective name for an electron beam tester analysis apparatus which irradiates an electron beam to an observing location and measures the generated secondary electron amount to obtain a potential image of the observing location. The installation area of the apparatus requires several square meters. There arises therefore a problem that a defect analysis of a semiconductor device and a wiring board cannot be made in a small space. There is also another problem that an EB tester itself is very expensive.

In order to obtain a clear displacement (flashing) potential image of a disconnection defect portion at a high precision, it is desired to apply a large irradiation current amount of an electron beam to the disconnection defect portion. However, if the irradiation current amount of an electron beam applied to a disconnection defect portion exceeds a threshold value, a state (irreversible charge-up) occurs in which the potential at a specimen surface does not recover the state without irradiation even if an electron beam irradiation is stopped, depending upon the type of a specimen, and resulting in a problem that a defect analysis cannot be made because of no change in a potential even if an electron beam is irradiated. It is very difficult to control electron beam irradiation at a high precision in order to eliminate such a problem, i.e., in order to prevent the irreversible charge-up and obtain a clear displacement (flashing) potential image of a disconnection defect portion at a high precision.

Instead of irradiating an electron beam directly to a defective wiring portion such as a disconnection defect as described above, if an electron beam is irradiated to a gate circuit of an inverter circuit connected to a defective wiring portion such as a disconnection defect and a potential image dislocating at the gate circuit or inverter circuit is obtained, a more clear potential image can be obtained. However, in order to supply an irradiation current amount at such a potential change level at which the irreversible charge-up will not occur and the gate circuit or inverter circuit is subjected to logical transition, very precise control for electron beam irradiation is required, which is very difficult to be realized.

According to JP-A-2001-141776, since a defective wiring portion is excited not by electron beam irradiation but with a magnetic field generation head to generate a potential change, the irreversible charge-up will not occur. However, since the EB tester is used to acquire at least a potential image, there arises a problem that a large working space is required and the apparatus itself is very expensive.

The present inventors have studied in various ways and have concluded that it is important to realize activation of a defective portion by an approach different from electron beam irradiation in order to solve the above-described problems. The present inventors have further concluded that it is desired to detect a variation in electric characteristics of a semiconductor integrated circuit by an approach different from potential image acquisition with an EB tester or the like.

It is an object of the present invention to provide a compact semiconductor or wiring defect analysis apparatus capable of identifying a defective portion correctly.

It is another object of the present invention to provide a manufacture method for a semiconductor device or a wiring board capable of improving a manufacture efficiency and yield.

In order to achieve the above objects, according to the representative aspects of the present invention, the following apparatuses and method are disclosed.

A defect analysis apparatus for a semiconductor integrated circuit characterized in that a presence/absence of a defect is detected by irradiating an electromagnetic field from a probe and detecting a power supply current variation or an electric characteristic variation in the semiconductor integrated circuit.

A defect analysis apparatus for a semiconductor integrated circuit characterized in that an open gate or a gate potential is activated and a power supply current variation, an electric characteristic variation or an electric, magnetic field distribution is detected or a current distribution is calculated, respectively in the semiconductor integrated circuit, to detect a presence/absence of a defect.

A defect analysis apparatus for a semiconductor integrated circuit, characterized in that a presence/absence of a defect is detected by measuring heat radiation, light emission radiation caused by a power supply current variation in the semiconductor integrated circuit.

A manufacture method for a semiconductor device comprising: a design step of designing a wiring pattern of the semiconductor device; a manufacture step of manufacturing the semiconductor device in accordance with the design information; an inspection step of inspecting the manufactured semiconductor device or the semiconductor device during manufacture; and an analysis/evaluation step of analyzing or evaluating the test result, wherein the analysis/evaluation step irradiates an electromagnetic field from a probe to a wiring of the semiconductor device, and detects a defect portion by detecting a power supply current variation, the semiconductor device is manufactured if the defect result clears predetermined conditions, whereas a defect reason is identified in accordance with the analysis result if the defect result does not clear the predetermined conditions, and the defect reason is fed back to manufacture processes.

Other objects, features and advantages of the present invention will become apparent from the following description of embodiments of the present invention when read in conjunction with the accompanying drawings.

### BRIEF DESCRIPTION OF THE DRAWINGS

FIG. 1 is a schematic diagram of a defect analysis apparatus.

FIG. 2 is a schematic diagram of a disconnection defect of an inverter circuit.

FIG. 3 is a schematic diagram of a defect analysis apparatus.

FIGS. 4A and 4B are diagrams showing waveforms according to an embodiment.

FIG. 5 is a schematic diagram of a defect analysis apparatus.

FIG. 6 is a schematic diagram of a defect analysis apparatus.

FIGS. 7A and 7B are schematic diagrams illustrating electric or magnetic field excitation on a substrate side.

FIG. 8 is a schematic diagram illustrating linkage to a CAD navigation system.

FIGS. 9A and 9B are schematic diagrams showing a defect analysis screen.

FIG. 10 is a diagram showing inverter circuit power supply current characteristics.

FIG. 11 is a process configuration flow chart.

FIG. 12 is a schematic diagram showing a first semiconductor manufacture process flow.

FIG. 13 is a schematic diagram showing a second semiconductor manufacture process flow.

### BEST MODE FOR CARRYING OUT THE INVENTION

Embodiments of the present invention will be described with reference to the accompanying drawings.

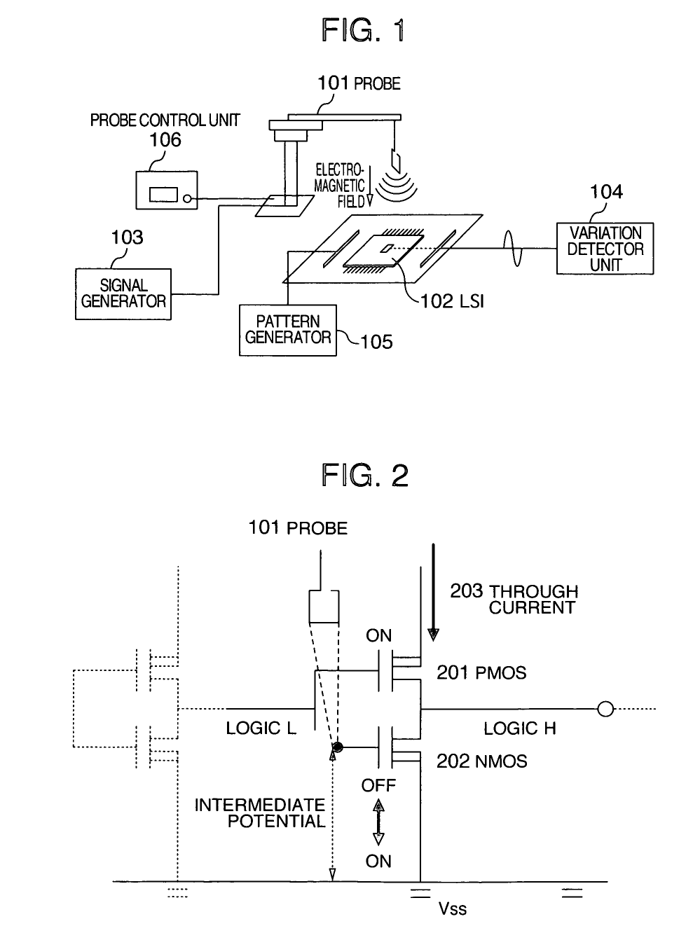

FIG. 1 shows a defect analysis apparatus for semiconductor integrated circuits according to a first embodiment of the present invention. The defect analysis apparatus of the embodiment comprises a probe 101, an LSI 102, a signal generator 103, a variation detector unit 104, a pattern generator unit 105 for setting an LSI to a desired state, and a probe control unit 106.

The semiconductor defect analysis apparatus of the embodiment: (a) changes an intermediate potential of an open gate by applying an electric field, a magnetic field or the like emitted from the probe 101; (b) activates a gate circuit or a gate potential to generate a through current 203; (c) varies a power supply current of the circuit; and (d) measures this power supply current variation with the variation detector unit 104 to thereby identify a presence/absence of a defect.

For example, the probe 101 is first excited by a power supplied from the signal generator unit 103 to make the probe 101 generate an electric or magnetic field. This electric or magnetic field is locally irradiated to a desired position of LSI 102 to thereby generate an electromotive force corresponding to the electric or magnetic field, in LSI.

This probe can irradiate an electric or magnetic field to an area from a micro area of about 0.1 μm to a broad area of several tens μm. When considering that the minimum wiring width is about 0.1 to 0.3 μm, this probe can irradiate an electric or magnetic field to a desired position, e.g., a particular circuit or element.

Next, description will be made on a difference between a normal wiring portion and a disconnection defect portion irradiated with an electric or magnetic field.

In a normal wiring portion, the gate potential of a connected inverter circuit or the like is driven in an arbitrary logic state. Therefore, even if an electric or magnetic field is irradiated to the normal wiring portion, the potential of the wiring portion hardly changes.

In a disconnection defect portion, as shown by a wiring breakdown defect of an inverter circuit of FIG. 2, the gate potential of an NMOS 202 connected to a disconnection defect is not driven in a predetermined logic state but remains at an intermediate potential between a low potential and a high potential (this is called open gate). As an electric or magnetic field is irradiated to the disconnection defect portion, the potential of the wiring portion changes.

Since this potential change activates the disconnection defect portion, both NMOS and PMOS turn on so that a through current flows and a power supply current changes from that of a normal circuit. A change in the power source current caused by the through current of a single gate circuit is about 1/10000 to 1/10 of the power source current, although it depends upon an activation level. This power source current variation is detected with the variation detector unit 104.

Next, detailed description will be made on a relation between the frequency of an excitation wave applied to the probe and a power source current variation.

FIG. 10 shows a simulation result of the power source current variation characteristics of the inverter circuit shown in FIG. 2, as an example of the power source current variation characteristics.

As apparent from FIG. 10, a power source current variation is formed proportionally with an intermediate potential variation. Therefore, in order to identify a disconnection defect portion with ease, it is desired to give a large potential change to the disconnection defect portion.

In order to give a large potential change to a disconnection defect portion, it is necessary to apply a large electric field intensity or magnetic field intensity to a wiring of LSI 102 and it is desired to drive the probe 101 with an excitation wave having a higher frequency. The reason for this is that by exciting the probe 101 at a higher frequency, a high density energy can be supplied to the probe 101, a large electric or magnetic field intensity can be supplied from the probe 101 to an irradiation portion, and a larger potential change is given to the breakdown wiring portion.

More specifically, according to a defect analysis method of the embodiment, if an electric or magnetic field is generated by using current (excitation wave) in a frequency band of several tens KHz to several hundreds MHz, defect analysis is possible even for a semiconductor device having a high operation frequency in the frequency band of several hundreds MHz.

According to the defect analysis apparatus of the first embodiment, since the potential at a defective wiring portion is changed (activated) not by using an electron beam but by using an electric or magnetic field generated by the probe, a change in the potential at the disconnection defect portion can be detected reliably and highly precisely without irreversible charge-up.

Since an EB tester is not necessary to be used, the defect analysis apparatus (defect analysis system) can be made compact.

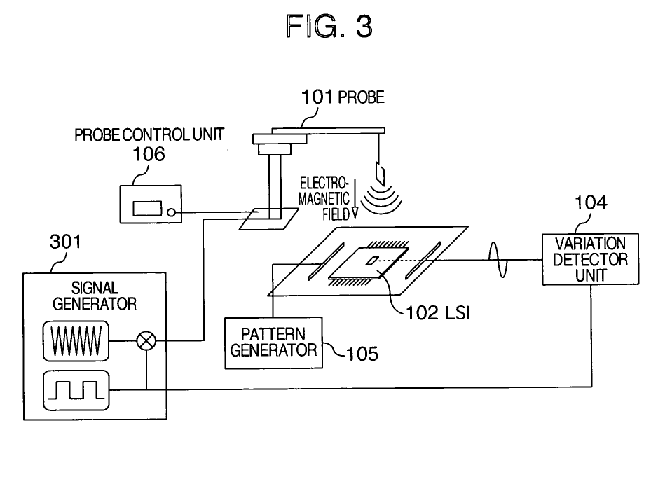

Next, with reference to FIG. 3, description will be made on a defect analysis apparatus, considering an operation of by-pass capacitors according to a second embodiment.

By-pass capacitors are added to an inside of a power supply system of LSI 102 or a test substrate mounted with LSI. With high frequency electric or magnetic field excitation, a power supply current variation caused by activation of a gate circuit occurs at a high frequency. Therefore, the variation is suppressed by the by-pass capacitors and is difficult to be detected with the variation detector unit 104. The defect analysis apparatus of this embodiment mitigates this problem.

The defect analysis apparatus of this embodiment comprises an electric or magnetic field probe 101, a variation detector unit 104, a pattern generator unit 105 for setting LSI to a desired state, a probe control unit 106, a signal generator 301 for modulating an excitation wave for supplying a power to the probe 101.

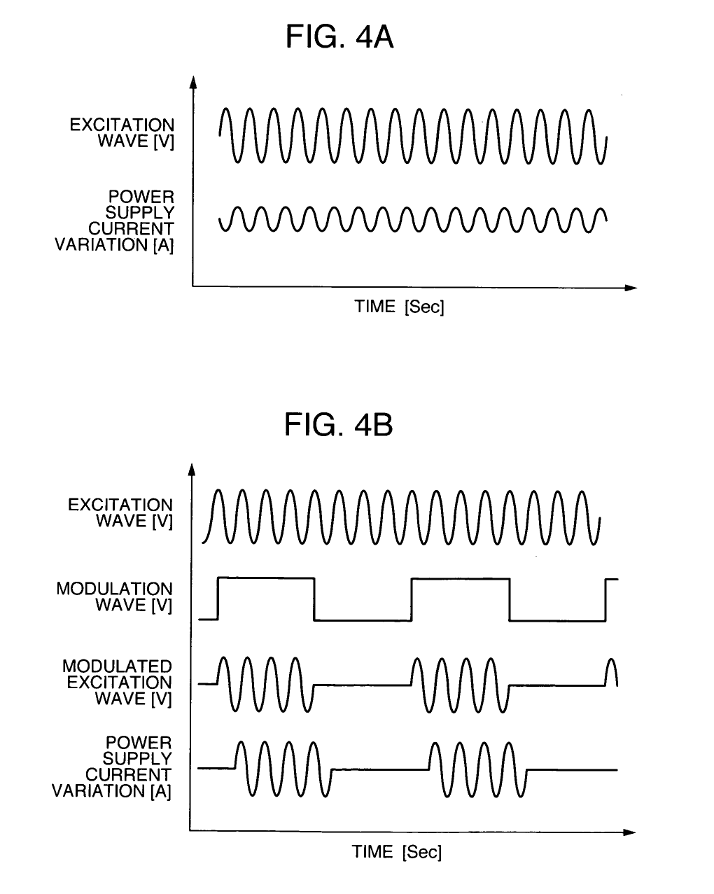

The signal generator 301 generate two signals having different frequencies, e.g., an excitation wave having a high frequency and a modulation wave having a frequency lower than that of the excitation wave. A modulated excitation wave is generated which is obtained by switching an excitation wave with a modulation wave, as shown in FIGS. 4A and 4B. The high frequency is preferably in a several tens MHz to GHz band and the low frequency is preferably in a several hundreds Hz to several tens KHz band.

The probe 101 is excited with this modulated excitation wave to irradiate an electric or magnetic field, activate a gate circuit connected to a disconnection defect portion and vary a power supply current of the circuit. The variation detector unit 104 detects a power supply current variation, synchronously with the modulation wave generated by the signal generator 301. FIGS. 4A and 4B show the excitation wave, modulation wave and a power supply current variation of the first and second embodiments, respectively.

In the second embodiment, since the excitation wave is modulated, it is possible to suppress the power supply current variation level from being lowered by by-pass capacitors. Namely, the influence of by-pass capacitors inside LSI can be reduced and a disconnection defect of LSI having by-pass capacitors can be analyzed highly precisely.

It is also possible to detect easily a power supply current variation level, irrespective of whether or not there are by-pass capacitors.

Modulation according to the embodiment of the invention is not limited only to the above-described modulation, but other various modulations such as AM modulation may also be used in the range not departing from the gist of the present invention.

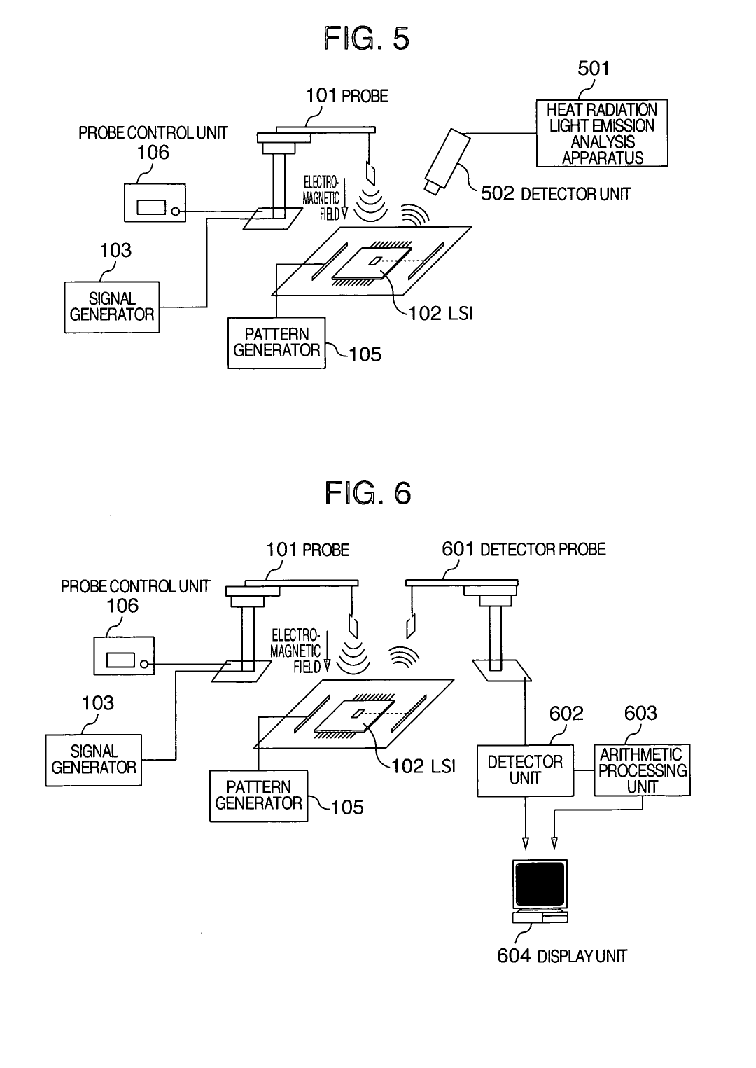

FIG. 5 is a schematic view showing a defect analysis apparatus according to a third embodiment. The detect analysis apparatus of this embodiment comprises a probe 101, an LSI 102, a signal generator 103, a pattern generator unit 105 for setting LSI to a desired state, a probe control unit 106, a heat radiation and light emission analysis apparatus 501 and a detector unit 502. An electric or magnetic field is irradiated from the probe 101 to vary the potential of an open gate, activate the gate circuit and vary a power supply current.

In contrast with the above-described embodiment in which a power supply current variation is measured electrically directly, in the third embodiment a presence/absence of a defect portion is detected by capturing a physical phenomenon of heat radiation and light emission radiation from a gate circuit or its nearby area to be caused when an open gate or a gate potential is activated.

FIG. 6 is a schematic diagram of a disconnection defect analysis apparatus according to a fourth embodiment of the present invention. The detect analysis apparatus of this embodiment comprises a probe 101, an LSI 102, a signal generator 103, a pattern generator unit 105 for setting LSI to a desired state, a probe control unit 106, a detector probe 601 and a detector unit 602.

Similar to the above-described embodiment, an electric or magnetic field is irradiated from the probe 101 to vary the potential of an open gate and activate the gate circuit. As the gate circuit is activated, an electric or magnetic field near the gate circuit changes.

In this embodiment, this nearby electric or magnetic field is measured with the detector probe 601 and detector unit 602 to thereby detect a presence/absence of a defect.

This embodiment has an arithmetic processing unit 603 which calculates the measured electric or magnetic field distribution so that the calculated current distribution can be displayed on a display unit 604. A power supply current variation caused by activating the gate circuit or gate potential is detected from the measured current distribution and a presence/absence of a defect can be detected.

According to the fourth embodiment, an electric or magnetic field distribution of a normal product LSI 102 is measured in advance or its current distribution is calculated. A presence/absence of a defect can be detected from difference information between the normal product and a defective product. For example, extracting the difference information is performed by the arithmetic processing unit 603 and displayed on the display unit 604.

In each embodiment described above, electric or magnetic field excitation by the probe 101 can be performed on the substrate side of LSI 102.

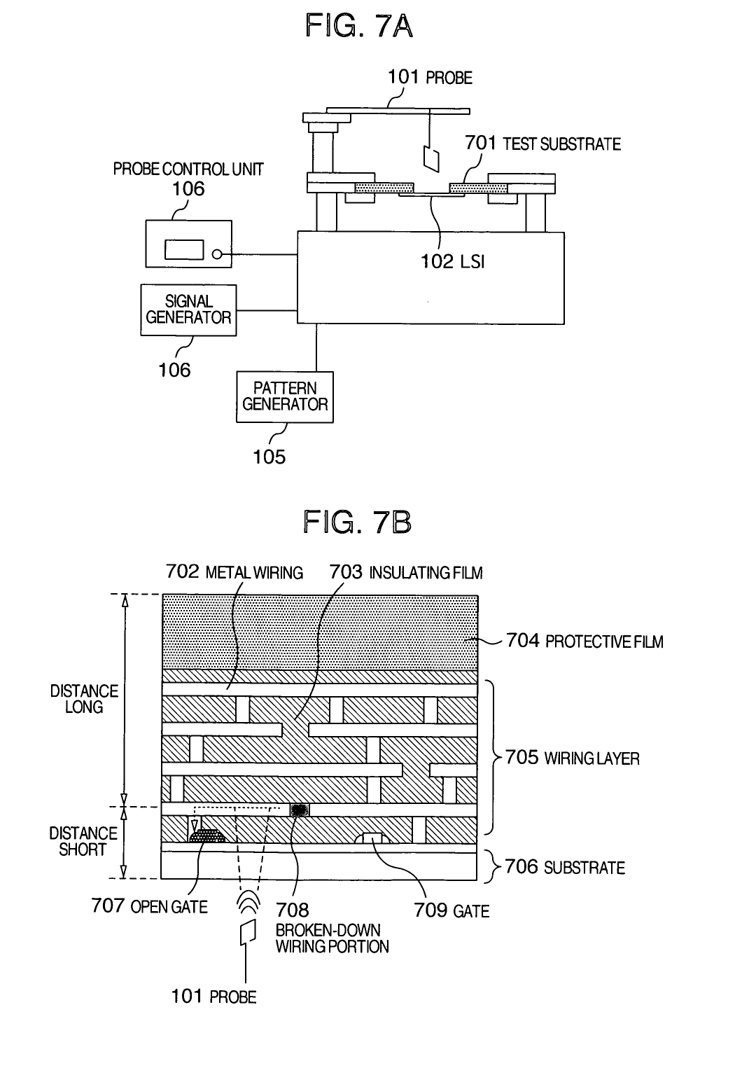

FIGS. 7A and 7B are schematic diagrams illustrating electric or magnetic field excitation on the substrate side of LSI 102.

With recent miniaturization and high integration of LSI, a mutilayer structure becomes dominant. Logic LSI products in particular have generally five or more wiring layers and a defect in a lower level wiring layer becomes more difficult to be detected.

In the above-described embodiments in which an electric or magnetic field is irradiated from an upper position of a substrate or a semiconductor device, if a defect of a multilayer wiring substrate is to be detected, activation of an open gate 707 or a gate potential becomes more difficult in some cases in the lower level wiring layer, because there are shielding regions such as an insulating film 703 for upper wiring layers, a metal wiring 702 and a protective film 704 such as PIQ.

In this embodiment, electric or magnetic field irradiation and excitation are performed for a defective portion in a lower level wiring layer of a multilayer wiring substrate, from the substrate side (from the lower layer side). When a defect portion is to be measured, the bottom of the LSI substrate 706 may be polished. Further, an electric or magnetic field may be irradiated from both the lower and upper layer sides of a multilayer wiring substrate to more precisely detect a defective portion.

According to this embodiment, wiring defect analysis is possible for a desired layer, e.g. of a lower layer, of a multilayer wiring substrate.

According to each of the above-described embodiments, an LSI defect can be detected as a power supply current variation, a light emission distribution, a heat radiation distribution, an electric or magnetic field distribution or a current distribution. Since local excitation is performed, it is possible to identify a defective portion having a predetermined area as a primary extraction. This area can be reduced by changing the excitation conditions and the excitation area or by performing analysis a plurality of times.

However, with recent miniaturization and high integration of LSI, it is very difficult for analyzer to manually identify a defective portion in a short time at a wiring level precision. There is also a possibility that a portion where abnormality is detected is different from an actual defective portion of a long distance wiring extending over a plurality of winging layers.

In this case, it becomes essential for an analyzer to perform secondary extraction of a defective portion of a wiring included in the area where abnormality is detected, through analysis such as returning upstream a wiring path with reference to design data.

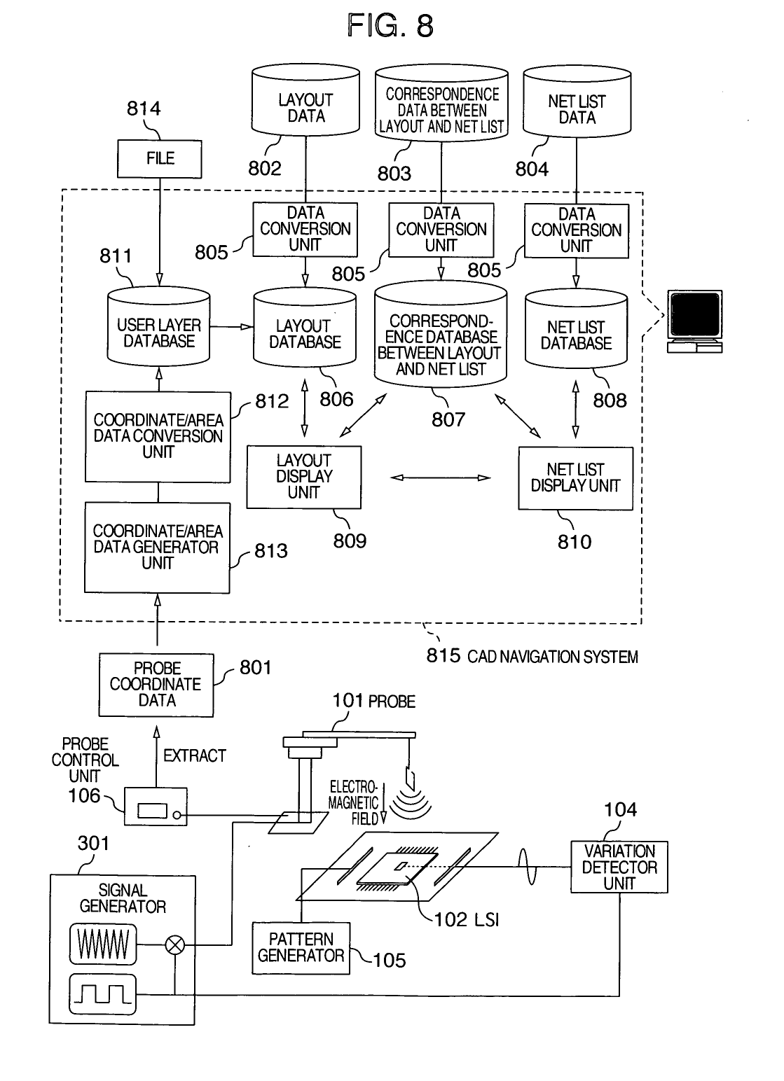

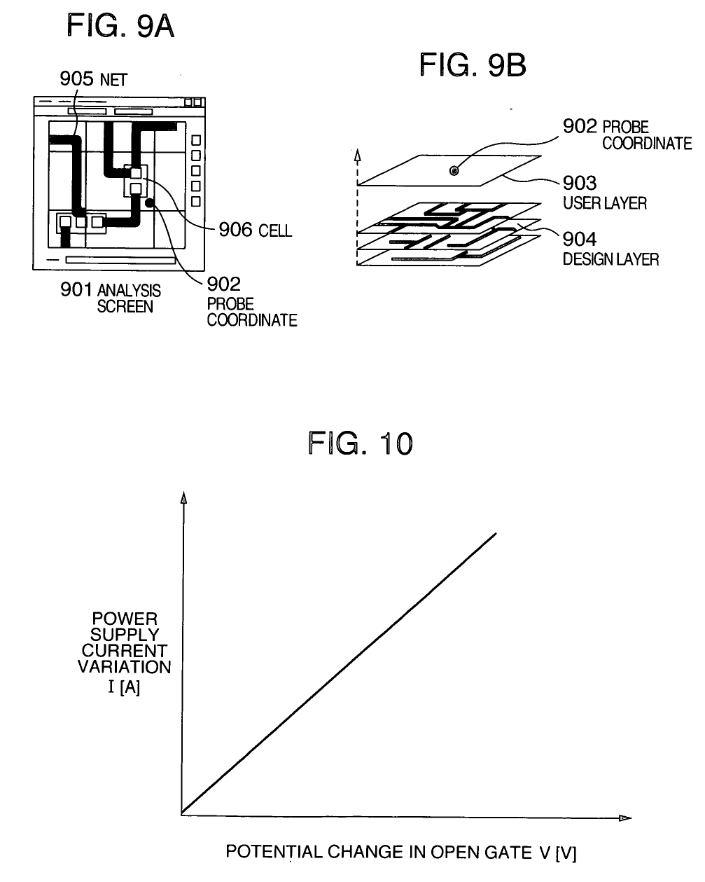

As technologies and a system for supporting to identify a defective portion of LSI 102, for example, it is desired to use a CAD navigation system 815 for navigating to identify a defective portion through correspondence between CAD design data of LSI to be inspected and coordinates detected during defect analysis. FIG. 8 is a schematic diagram showing an embodiment of defect analysis using the CAD navigation system 815. Probe coordinate data 801 extracted by a probe control unit 106 is output to and stored in a user layer database 811 via a coordinate/area data generator unit 813 and a coordinate/area data conversion unit 812. Data in the user layer database 811 can be dealt with at the same index as that of LSI design layout data. The coordinate/area data generator unit 813 designates the probe coordinate data 801 as the coordinate data of a center of gravity so that the region having an area which a user conditionally sets as desired, can be used as an analysis area. The coordinate/area data conversion unit 812 converts this analysis data into polygon data and into layout data 907 at a user layer shown in FIG. 9B which is then stored in the user layer database 811. Various data in an arbitrary file format 814 can be externally stored in the user layer database 811. Examples of this data include DUT net cell information obtained by various analysis apparatuses such as an IDDQ analysis apparatus, layout pattern information with severe process margins, analysis weighing conditions obtained from the past defect analysis, and other data.

Input as LSI design data in the system are layout data 802, correspondence data 803 between a layout and a net list, and net list data 804. Each data is stored via data conversion units 805 into a layout database 806, a layout/net list correspondence database 807, and a net list database 808. Each database is mutually linked. A design layout and net list information corresponding to the probe coordinate data can be output to and displayed on a layout display unit 809 and a net list display unit 810, respectively, a correspondence between the design layout and net list information being given.

FIGS. 9A and 9B are schematic diagrams showing an analysis screen 901 of the CAD navigation system 815 of the embodiment. Output to and displayed on this screen at a design layer 904 are probe coordinate data 902 input at a user layer 903 and design layout data for each wiring layer of LSI. A net 905 and cells 906 coincident with or adjacent to the probe coordinate data 902 for each wiring layer can be displayed and extracted on the analysis screen 901. The layout data 907 generated by using the probe coordinate data 902 as the coordinate data of the center of gravity can also be displayed on the analysis screen 901, and a user can magnify or reduce an analysis area as desired by setting conditions on the screen. A plurality of probe coordinate data sets 902 and layout data sets 907 can be displayed on the analysis screen 901, and an analyzer can visually discriminate between them through designation, change or the like of a display color.

By using the CAD navigation system, a defect can be identified correctly in a short time at a wiring level during defect analysis of a semiconductor integrated circuit. In analysis by a plurality of analysis apparatuses such as a light emission analysis apparatus and an OBIRCH analysis apparatus, it is possible to converge defect candidates, make a particular work efficient, and shorten an analysis time.

In a manufacture process for a semiconductor integrated circuit (hereinafter called LSI), shortening a defect analysis time is a very important issue in order to shorten a process configuration period and realize an early startup of a process line.

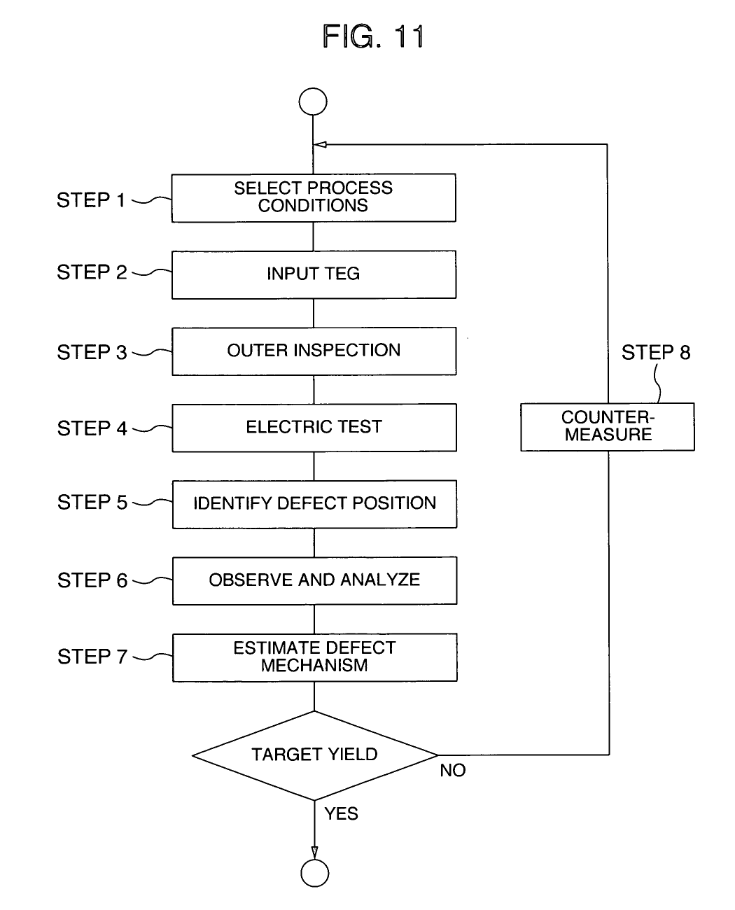

Description will be made on process configuration with reference to a flow chart shown in FIG. 11. After process conditions are set (STEP 1), a TEG manufacture process is set and Si wafers are input to a manufacture line to start manufacture (STEP 2). In this manufacture process, a wafer exterior inspection (foreign matter inspection after a film forming process, exterior inspection after etching and CMP, SEM review after inspection, and the like) is performed between predetermined processes and after a predetermined processes (STEP 3), and thereafter an electronic test is performed with a tester, a probe or the like to judge whether TEG is defective or not (STEP 4). In accordance with the results of the exterior inspection and electronic test, defect analysis is executed to identify a defective position (STEP 5). In accordance with the identified coordinates, the surface and cross section are observed and the material is analyzed with SEM or TEM (STEP 6). Defect mechanism is estimated and a countermeasure is established (STEP 7). It is determined whether the initial target yield has been accomplished or not, and a desired countermeasure (process improvements, apparatus improvements, apparatus cleaning or the like) is executed (STEP 8) and the results are reflected upon subsequent lots to confirm the effects.

Since a series of processes shown in the flow chart is repetitively performed to enhance the reduction in defects and perform process configuration, shortening a defect analysis time results in earlier process configuration.

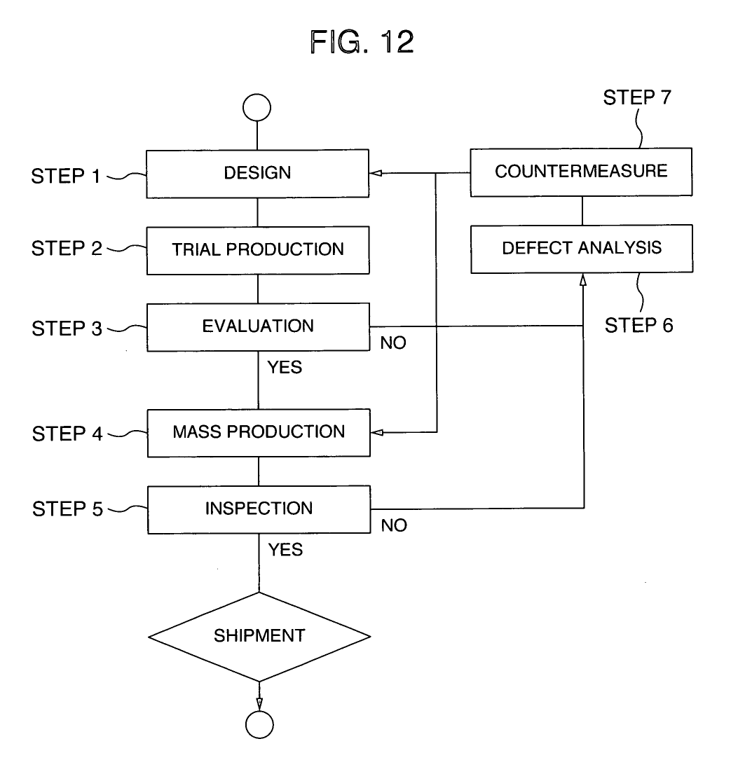

FIG. 12 is a schematic diagram illustrating a manufacture process flow for a semiconductor product.

Defect analysis is an essential and indispensable process flow in order to configure a process and change design conditions at a design stage and in order to improve a yield and realize a defect countermeasure at a mass production stage. The effects of this embodiment not only simplify a defect analysis apparatus and an analysis work but also cover a wide range including a semiconductor manufacture process, a semiconductor manufacture method and processes.

Specific description will be made on a semiconductor device manufacture method. In a semiconductor device manufacture method, mass production of devices starts after a design (function, theory, circuit) process, a trial production process, an evaluation process, a defect analysis process, a countermeasure process and the like, in accordance with market researches and customer needs. A mass production process includes a process of fabricating circuit elements on a wafer, a process of inspecting semiconductor elements on the wafer, a process of dicing the wafer, and a process of forming leads and bumps on each semiconductor chip.

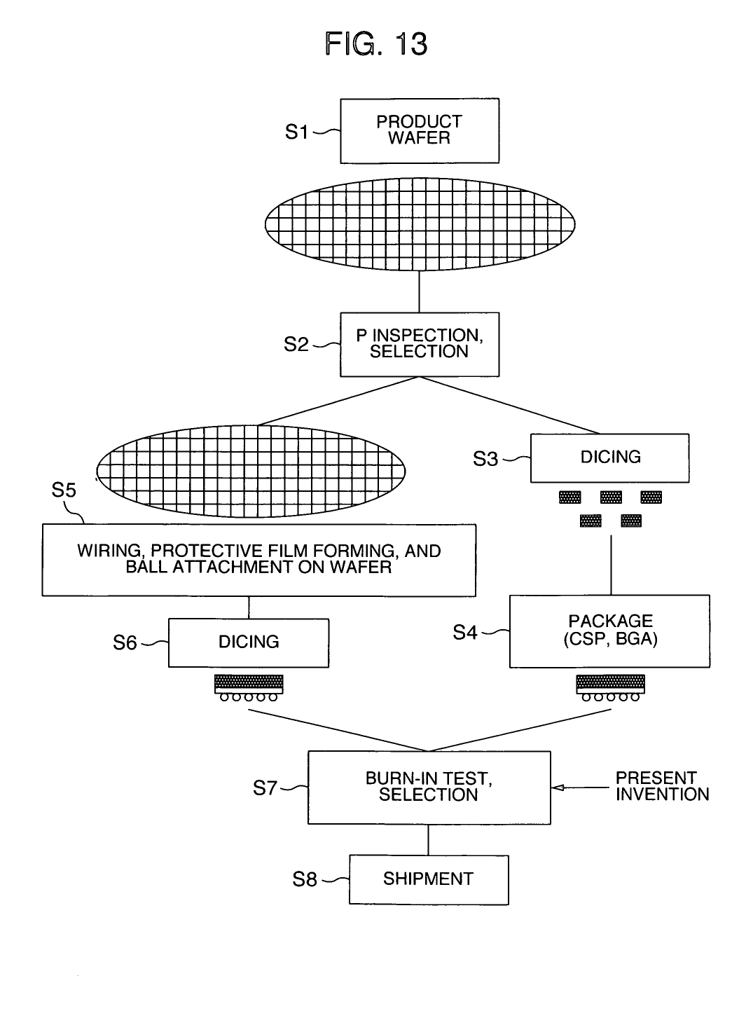

FIG. 13 is a manufacture flow chart for a semiconductor device. Referring to FIG. 13, a product wafer manufactured at Step S21 is subjected to an initial defect selection by a P inspection (pellet inspection) at Step S2. A selected normal wafer is subjected to Step S3 or S5. Whether the flow advances to Step S3 or S5 is selected in accordance with manufacture facilities and the like.

The product wafer is diced at Step S3 and only normal chips are packaged into chip size packages (CSP), ball grid arrays (BGA) and the like at Step S4 to thereafter advance to Step S7.

At Step S5 wiring patterns and a protective film are formed collectively on a wafer, and then solder balls are mounted. Next, at Step S6 the wafer with the wiring patterns and the like is diced into chips to thereafter advance to Step S7.

At Step S7 a semiconductor inspection method is executed by using a semiconductor element inspection socket. Namely, each divided individual final product is mounted on an IC inspection socket to be subjected to a burn-in test to select a final product. Products eventually determined as normal products are shipped at Step S8. Recently, there are wafer level chip size packages in which semiconductor devices are formed by dicing a wafer after inspection is performed and rewiring and external connection terminals are formed at a wafer level.

The manufacture of semiconductor devices described above is performed in accordance with designs made by the first process among the semiconductor manufacture processes. In accordance with the information obtained by the evaluation and inspection processes, defect analysis is executed to grasp the defect reason to adopt a proper countermeasure in the design process such as changing a manufacture process. These processes are very important for subsequent mass production processes. Namely, the effects of defect analysis, such as improvements on a yield at a mass production stage, are reflected to all devices.

The invention made by the present inventors has been described specifically in connection with the embodiments. The present invention is not limited to the above-described embodiments, but it is needless to say that various modifications are possible without departing from the gist of the invention.

Typical aspects disclosed in the above-described embodiments are as follows.

(1) A defect analysis apparatus for a semiconductor integrated circuit characterized in that a presence/absence of a defect is detected by irradiating an electromagnetic field from a probe and detecting a power supply current variation.

(2) A defect analysis apparatus for a semiconductor integrated circuit characterized in that a presence/absence of a defect is detected by irradiating an electromagnetic field from a probe and detecting a voltage variation, an impedance variation or an electric characteristic variation.

(3) A defect analysis apparatus for a semiconductor integrated circuit described in (1) or (2), characterized in that the power supply current variation, the voltage variation, or the impedance variation is detected by activating an open gate or a gate potential.

(4) A defect analysis apparatus for a semiconductor integrated circuit described in any one of (1) to (3), characterized in that the power supply current variation, the voltage variation or the impedance variation is detected by exciting the probe with modulation and synchronizing with a signal applied to the probe.

(5) A defect analysis apparatus for a semiconductor integrated circuit described in any one of (1) to (4), characterized in that a defect is detected by measuring heat radiation and light emission radiation caused by the power supply current variation, the voltage variation or the impedance variation.

(6) A defect analysis apparatus for a semiconductor integrated circuit characterized in that an electric characteristic variation in the semiconductor integrated circuit is detected by activating an open gate or a gate potential.

(7) A defect analysis apparatus for a semiconductor integrated circuit described in (5), characterized in that a power supply current variation is applied to the semiconductor circuit and an open gate or a gate potential is activated.

(8) A defect analysis apparatus for a semiconductor integrated circuit described in (6) or (7), characterized in that the open gate or the gate potential is activated by irradiating an electromagnetic field from a probe.

(9) A defect analysis apparatus for a semiconductor integrated circuit described in (8), characterized in that the electric characteristic variation is detected by exciting the probe with modulation and synchronizing with a signal applied to the probe.

(10) A defect analysis apparatus for a semiconductor integrated circuit described in any one of (1) to (9), characterized in that a defect position is identified from differential information on a defective product and on a normal product.

(11) A defect analysis apparatus for a semiconductor integrated circuit described in any one of (1) to (10), characterized in that irradiation of an electromagnetic field from the probe or activation of the open gate or the gate potential is performed on a substrate side.

(12) A defect analysis apparatus for a semiconductor integrated circuit described in any one of (1) to (11), characterized in that a defect portion is determined by mutually referring to position information on the probe and design information on a chip.

(13) A defect analysis apparatus for a semiconductor integrated circuit described in (12), characterized in that if a defect portion and a detected abnormal portion are different, a wiring path of a wiring including an area of the detected abnormal portion is analyzed by referring to design data.

(14) A manufacture method for a semiconductor device comprising: a design step of designing a wiring pattern of the semiconductor device; a manufacture step of manufacturing the semiconductor device in accordance with the design information; an inspection step of inspecting the manufactured semiconductor device or the semiconductor device during manufacture; and an analysis/evaluation step of analyzing or evaluating the test result, wherein the analysis/evaluation step irradiates an electromagnetic field from a probe to a wiring of the semiconductor device, and detects a defect portion by detecting a power supply current variation, the semiconductor device is manufactured if the defect result clears predetermined conditions, whereas a defect reason is identified in accordance with the analysis result if the defect result does not clear the predetermined conditions, and the defect reason is fed back to manufacture processes.

According to the embodiments described above, in a semiconductor integrated circuit, an open gate or a gate potential is activated to generate and detect a power supply current variation so that a presence/absence of a defective portion can be detected. Since an electron beam, an EB tester for acquiring a potential image and a vacuum system are not necessary, the problems of a large scale apparatus and high cost can be mitigated, and analysis works can be simplified by using simple facilities. Through linkage to a CAD navigation system, it is possible to refer to a correspondence between probe position information and chip design information. Accordingly, a defective portion can be identified correctly, an analysis time can be shortened, and a defect countermeasure can be adopted quickly. With these advantageous effects, it becomes possible to shorten a process configuration period and realize an earlier startup of a process line. In a mass production factory, various countermeasures matching defect factors can be adopted quickly because of a shortened defect analysis time, such as defect countermeasures for manufacture apparatuses and manufacture conditions change. This is very effective for earlier recovery from a spontaneous lowered yield and improved yield during product manufacture startup.

The present invention has been made in connection with the embodiments. The present invention is not limited to the embodiments, but it is apparent for those skilled in the art that various changes and modifications are possible without departing from the gist of the present invention and the scope of appended claims.

### INDUSTRIAL APPLICABILITY

According to the present invention, it is possible to provide a compact semiconductor or wiring defect analysis apparatus capable of correctly identifying a defect portion.

In a semiconductor or wiring substrate manufacture method, it is possible to improve a manufacture efficiency and a yield.

1. A defect analysis apparatus for a semiconductor integrated circuit characterized in that a presence/absence of a defect is detected by irradiating an electromagnetic field from a probe and detecting a power supply current variation.

2. A defect analysis apparatus for a semiconductor integrated circuit characterized in that a presence/absence of a defect is detected by irradiating an electromagnetic field from a probe and detecting a voltage variation, an impedance variation or an electric characteristic variation.

3. The defect analysis apparatus for a semiconductor integrated circuit according to claim 1, characterized in that said power supply current variation, said voltage variation, or said impedance variation is detected by activating an open gate or a gate potential.

4. The defect analysis apparatus for a semiconductor integrated circuit according to claims 1, characterized in that said power supply current variation, said voltage variation or said impedance variation is detected by exciting the probe with modulation and synchronizing with a signal applied to the probe.

5. The defect analysis apparatus for a semiconductor integrated circuit according to claims 1, characterized in that a defect is detected by measuring heat radiation and light emission radiation caused by said power supply current variation, said voltage variation or said impedance variation.

6. A defect analysis apparatus for a semiconductor integrated circuit characterized in that an electric characteristic variation in the semiconductor integrated circuit is detected by activating an open gate or a gate potential.

7. The defect analysis apparatus for a semiconductor integrated circuit according to claim 6, characterized in that a power supply current variation is applied to the semiconductor integrated circuit and the open gate or the gate potential is activated.

8. The defect analysis apparatus for a semiconductor integrated circuit according to claim 6, characterized in that the open gate or the gate potential is activated by irradiating an electromagnetic field from a probe.

9. The defect analysis apparatus for a semiconductor integrated circuit according to claim 8, characterized in that said electric characteristic variation is detected by exciting the probe with modulation and synchronizing with a signal applied to the probe.

10. The defect analysis apparatus for a semiconductor integrated circuit according to claims 1, characterized in that a defect position is identified from differential information on a defective product and on a normal product.

11. The defect analysis apparatus for a semiconductor integrated circuit according to claim 3, characterized in that irradiation of an electromagnetic field from the probe or activation of the open gate or the gate potential is performed on a substrate side.

12. The defect analysis apparatus for a semiconductor integrated circuit according to claim 1, characterized in that a defect portion is determined by mutually referring to position information on the probe and design information on a chip.

13. The defect analysis apparatus for a semiconductor integrated circuit according to claim 12, characterized in that if a defect portion and a detected abnormal portion are different, a wiring path of a wiring including an area of the detected abnormal portion is analyzed by referring to design data.

14. A manufacture method for a semiconductor device comprising: a design step of designing a wiring pattern of the semiconductor device; a manufacture step of manufacturing the semiconductor device in accordance with the design information; an inspection step of inspecting the manufactured semiconductor device or the semiconductor device during manufacture; and an analysis/evaluation step of analyzing or evaluating the test result, wherein the analysis/evaluation step irradiates an electromagnetic field from a probe to a wiring of the semiconductor device, and detects a defect portion by detecting a power supply current variation, the semiconductor device is manufactured if the defect result clears predetermined conditions, whereas a defect reason is identified in accordance with the analysis result if the defect result does not clear the predetermined conditions, and the defect reason is fed back to manufacture processes.

15. The defect analysis apparatus for a semiconductor integrated circuit according to claim 2, characterized in that said voltage variation or said impedance variation is detected by activating an open gate or a gate potential.

16. The defect analysis apparatus for a semiconductor integrated circuit according to claim 2, characterized in that said voltage variation or said impedance variation is detected by exciting the probe with modulation and synchronizing with a signal applied to the probe.

17. The defect analysis apparatus for a semiconductor integrated circuit according to claim 2, characterized in that a defect is detected by measuring heat radiation and light emission radiation caused by said voltage variation or said impedance variation.
